(19) United States
(12) Patent Application Publication
(10) Pub. No.: US 2025/0273621 A1
(43) Pub. Date: Aug. 28, 2025

(54) SUBSTRATE PROCESSING METHOD, PLASMA PROCESSING APPARATUS, AND SUBSTRATE PROCESSING SYSTEM

(71) Applicant: Tokyo Electron Limited, Tokyo (JP)

(72) Inventors: Kenji OUCHI, Nirasaki City (JP); Yoshihisa MATSUBARA, Tokyo (JP); Yuichiro INATOMI, Nirasaki City (JP); Yuki KIKUCHI, Nirasaki City (JP)

(21) Appl. No.: 19/206,350

(22) Filed: May 13, 2025

Related U.S. Application Data
(63) Continuation of application No. PCT/JP2023/041115, filed on Nov. 15, 2023.

(30) Foreign Application Priority Data
Nov. 17, 2022 (JP) 2022-184422

(51) Int. Cl. H01L 23/00

(52) U.S. Cl. CPC H01L 24/80; H01L 24/74; H01L 24/05; H01L 2224/05647; H01L 2224/74; H01L 2224/8002; H01L 2224/80895; H01L 2224/80896; H01L 2224/80948

(57) ABSTRACT

A substrate processing method includes activating a surface of a substrate having a conductive layer containing Cu and an insulating layer by exposing the substrate to plasma of a first process gas, forming an oxidation suppression layer that suppresses oxidation of Cu on a surface of the conductive layer by exposing the substrate after activating the surface of the substrate to plasma of a second process gas, forming a hydroxyl group on the surface of the substrate by supplying water to the surface of the substrate after forming the oxidation suppression layer, bonding the substrate after forming the hydroxyl group to another substrate after forming the hydroxyl group, and heat-treating the bonded substrates.

### CROSS-REFERENCE TO RELATED APPLICATION

This application is a bypass continuation application of international application No. PCT/JP2023/041115 having an international filing date of Nov. 15, 2023 and designating the United States, the international application being based upon and claiming the benefit of priority from Japanese Patent Application No. 2022-184422, filed on Nov. 17, 2022, the entire contents of which are incorporated herein by reference.

### TECHNICAL FIELD

The present disclosure relates to a substrate processing method, a plasma processing apparatus, and a substrate processing system.

### BACKGROUND

Patent Document 1 discloses a method of manufacturing a semiconductor device, including preparing a semiconductor substrate having a copper film or a copper-containing metal film exposed on the surface of the semiconductor substrate, forming a metal film made of either a cobalt-tungsten based metal or tungsten on the copper film or copper-containing metal film, introducing Si into the metal film, and nitriding the metal film into which Si has been introduced.

### PRIOR ART DOCUMENTS

### Patent Documents

Patent Document 1: Japanese patent laid-open publication No. 2009-016520

### SUMMARY

According to one embodiment of the present disclosure, there is provided a substrate processing method including activating a surface of a substrate having a conductive layer containing Cu and an insulating layer by exposing the substrate to plasma of a first process gas, forming an oxidation suppression layer that suppresses oxidation of Cu on a surface of the conductive layer by exposing the substrate after activating the surface of the substrate to plasma of a second process gas, forming a hydroxyl group on the surface of the substrate by supplying water to the surface of the substrate after forming the oxidation suppression layer, bonding the substrate after forming the hydroxyl group to another substrate after forming the hydroxyl group, and heat-treating the bonded substrates.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an exemplary flowchart illustrating a method of bonding substrates.

FIG. 2A is an exemplary schematic cross-sectional view of a substrate in each process.

FIG. 2B is an exemplary schematic cross-sectional view of a substrate in each process.

FIG. 2C is an exemplary schematic cross-sectional view of a substrate in each process.

FIG. 2D is an exemplary schematic cross-sectional view of a substrate in each process.

FIG. 3A is an exemplary schematic cross-sectional view of a substrate in each process.

FIG. 3B is an exemplary schematic cross-sectional view of a substrate in each process.

FIG. 3C is an exemplary schematic cross-sectional view of substrates in each process.

FIG. 3D is an exemplary schematic cross-sectional view of a substrate in each process.

FIG. 4A is an exemplary schematic cross-sectional view of substrates in each process.

FIG. 4B is an exemplary schematic cross-sectional view of a substrate in each process.

FIG. 5 is an exemplary schematic cross-sectional view of a substrate for explaining photocorrosion.

FIG. 6A is an exemplary model diagram illustrating oxidation of a conductive layer in a reference example.

FIG. 6B is an exemplary model diagram illustrating oxidation of a conductive layer in the reference example.

FIG. 7A is an exemplary model diagram illustrating oxidation of a conductive layer according to the present disclosure.

FIG. 7B is an exemplary model diagram illustrating oxidation of the conductive layer according to the present disclosure.

FIG. 8 is a graph illustrating an exemplary X-ray photoelectron spectroscopy (XPS) analysis result.

FIG. 9 is a graph illustrating an exemplary XPS analysis result.

FIG. 10 is a graph illustrating an exemplary XPS analysis result.

FIG. 11 is a graph illustrating an exemplary XPS analysis result.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the accompanying drawings. In each drawing, the same components are denoted by the same reference numerals, and the description thereof may be omitted.

### <Bonding of Substrates>

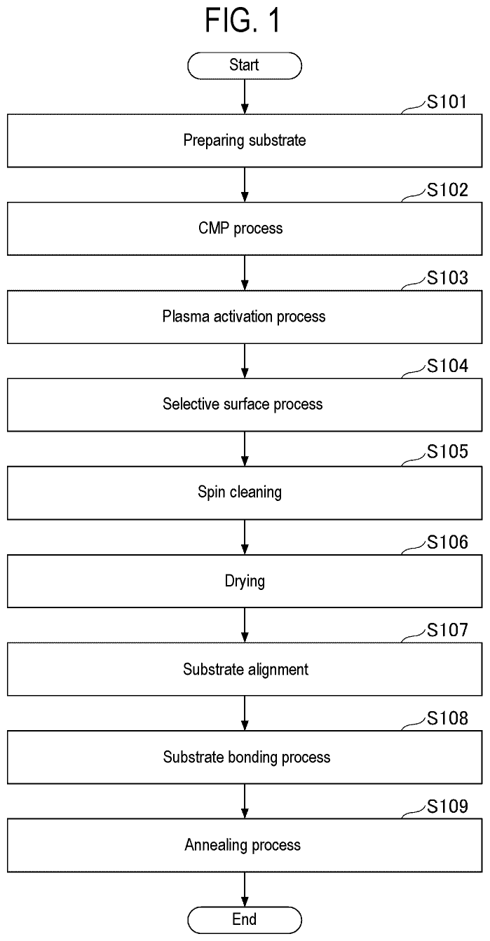

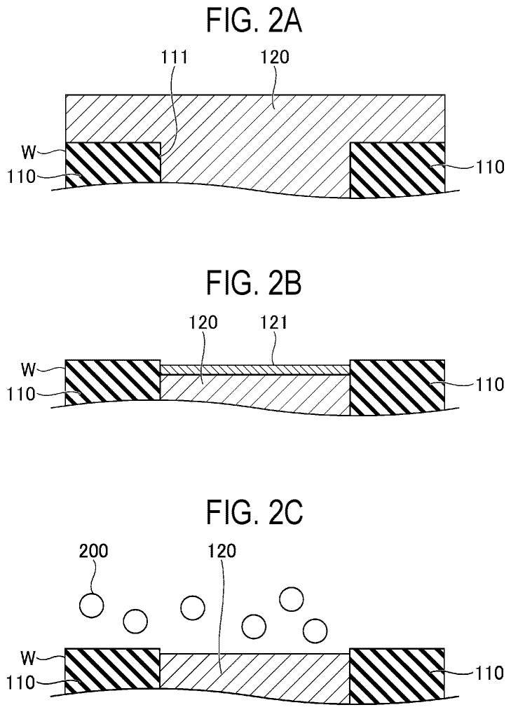

A method of bonding substrates W according to one embodiment will now be described with reference to FIGS. 1 to 4B. FIG. 1 is an exemplary flowchart illustrating a method of bonding the substrates W. Here, the substrates W (W1 and W2) having an insulating layer 110 and a conductive layer 120 are bonded. In FIGS. 2A to 4B, a portion of the surface of the substrate W is illustrated, and the other portions thereof are not illustrated.

In step S101, the substrate W is prepared.

FIG. 2A is an exemplary schematic cross-sectional view of the substrate W prepared in step S101. The substrate W has an insulating layer 110 and a conductive layer 120. The insulating layer 110 is made of an insulating material. The insulating layer 110 is, for example, SiO₂. A recess 111 such as a via, a hole, or a trench is formed in the insulating layer 110. The conductive layer 120 is made of Cu or a metal material containing Cu. The conductive layer 120 is formed over the recess 111 of the insulating layer 110 and the upper surface of the insulating layer 110. The conductive layer 120 is, for example, a wiring layer that connects to a semiconductor device (not illustrated) formed on the substrate W. That is, the substrate W is a substrate on which the semiconductor device is formed by a semiconductor device formation process and a back end of line (BEOL) having the insulating layer 110 and the conductive layer 120 by a wiring process is formed.

In step S102, a chemical mechanical polishing (CMP) process is performed on the substrate W using a CMP processing module. The surface of the substrate W is polished by the CMP process, and the conductive layer 120 formed on the upper surface of the insulating layer 110 is removed. An upper surface of the insulating layer 110 and an upper surface of the conductive layer 120 are formed to be flat by the CMP process.

In consideration of thermal expansion of the conductive layer 120 by an annealing process (see step S109) described later, the surface of the conductive layer 120 may be formed to be lower than the surface of the insulating layer 110. For example, after the CMP process is performed, the surface of the conductive layer 120 may be formed to be lower than the surface of the insulating layer 110 by etching the conductive layer 120 with water containing CO₂. When etching the conductive layer 120 with water containing CO₂, it is desirable to perform the etching process in a dark room in order to suppress photocorrosion described later.

FIG. 2B is an exemplary schematic cross-sectional view of the substrate W after step S102 is performed. Here, the surface (upper surface) of the substrate W has a first region formed of the insulating layer 110 and a second region formed of the conductive layer 120. In addition, the surface of the conductive layer 120 is formed to be lower than the surface of the insulating layer 110.

As illustrated in FIG. 2B, a modified layer 121 is formed on the surface of the conductive layer 120. The modified layer 121 is a layer generated during the CMP process and also includes a layer formed to suppress corrosion or oxidation of the outermost surface of the conductive layer 120. The modified layer 121 is formed of, for example, an adsorption layer of benzotriazole (BTA), or CuO, CuO₂, or Cu(OH)₂ generated during the CMP process.

In step S103, a plasma activation process is performed on the substrate W using a plasma processing apparatus. Here, the surface of the conductive layer 120 is cleaned and the surface of the insulating layer 110 is activated by exposing the substrate W to plasma of a first process gas 200. Here, it is desirable to use a gas containing H (hydrogen) and/or N (nitrogen), plasma of a noble gas such as Ar, or the like. The gas containing H (hydrogen) and/or N (nitrogen) is H₂ gas, N₂ gas, NH₃ gas, a mixed gas of H₂ and N₂, or a mixed gas of H₂ and NH₃. In order to suppress oxidation of the surface of the conductive layer 120, it is desirable to use plasma generated from a gas that does not contain O (oxygen).

FIG. 2C is an exemplary schematic cross-sectional view of the substrate W during the process of step S103. Benzotriazole (BTA) and the like on the surface of the substrate W are removed by exposing the surface of the substrate W to plasma. In addition, the surface of the conductive layer 120 is reduced by exposing the surface of the substrate W to plasma. As a result, the modified layer 121 (see FIG. 2B) is removed from the surface of the conductive layer 120, and thus the surface of the conductive layer 120 is cleaned.

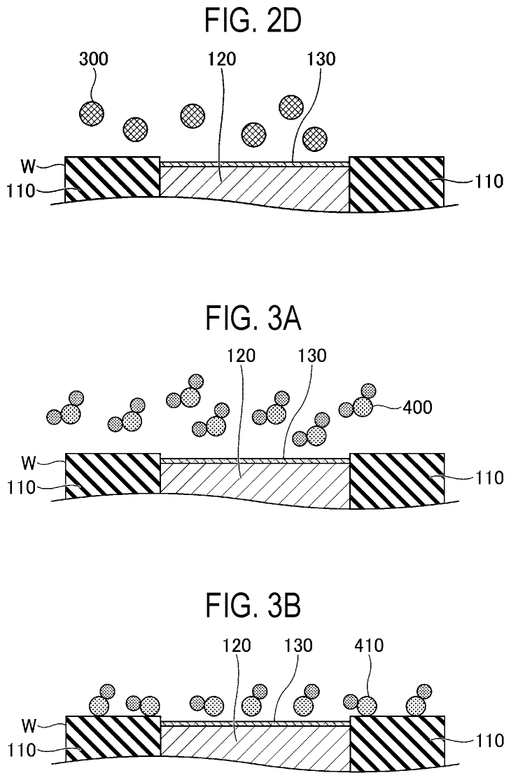

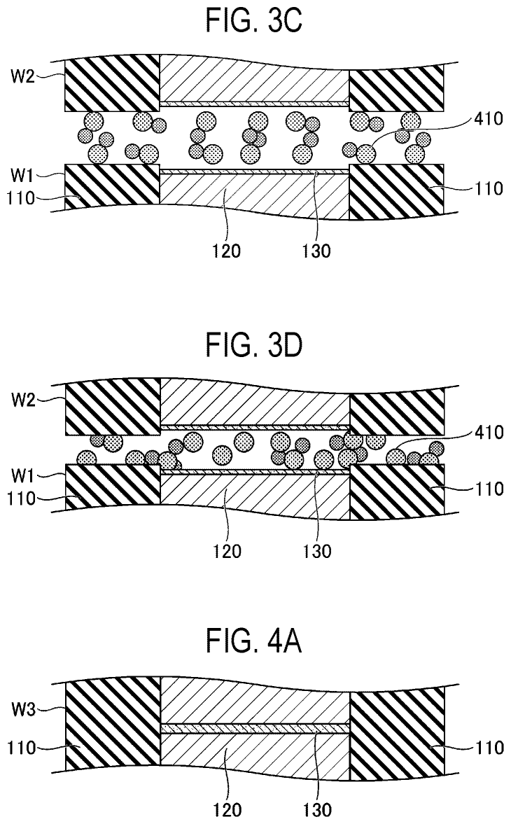

Further, by exposing the surface of the substrate W to plasma, a termination group on the surface of the insulating layer 110 is cut, thereby forming an active surface (not illustrated) on the surface of the insulating layer 110. As a result, the surface of the insulating layer 110 is in a state in which a hydroxyl group 410 (see FIG. 3B) described later can be easily adsorbed.

In step S104, a second process gas 300 is supplied to the substrate W using the plasma processing apparatus to perform a selective surface process on the conductive layer 120. Here, the second process gas 300 uses a gas including an atom that easily forms a bond with the Cu of the conductive layer 120 and also forms a stronger bond with O (oxygen) than a bond of Cu—O. In other words, the second process gas 300 uses a gas including an atom that has a high diffusion rate to Cu of the conductive layer 120 and has higher oxide stability than Cu (an atom that is preferentially oxidized compared to Cu). In other words, in a bonding reaction with O (oxygen), a gas including an atom having Gibbs energy lower than that of Cu is used as the second process gas 300.

Specifically, a gas including Si or a gas including Al can be used as the second process gas 300. As the gas including Si, for example, any one of SiH₄, Si₂H₆, SiCl₄, Si₂Cl₂H₂, Si₂Cl₆ (HCD), SiH₂(C₂H₅)₂, Si₂H₃Cl₃, Si(SiH₃)₄, N[Si(CH₃)₃][SiHCH₃N(CH₃)₂]₂, N(SiH₃)₃, N(Si₂H₅)₃, SiH[N(CH₃)₂]₃, SiCl₂(CH₃)₂, SiH₂[NH(t-C₄H₉)]₂, SiH₃[N(i-C₄H₇)₂], and SiH(CH₃)₃ can be used. As the gas including Al, for example, any one of AlCl₃, Al(CH₃)₃ (TMA), AlH(CH₃)₂ (DMAH), Al(CH₃)₂Cl, Al(C₂H₅) ₃, Al(C₄H₉)₃, Al[N(C₂H₅)₂]₃, Al[N(C₂H₅)₂]₂[C₃H₆N(CH₃)₂], Al[O(CH₃)₂CH₂OCH₃]₃, Al[N(i-C₃H₇)₂]₃, Al(CH₃)₂[C₃H₆(CH₃)₂], and AlH₂[N(t-C₄H₉) CH₂CH₂N (CH₃)₂] can be used. In the following description, SiH₄ will be used as the second process gas 300.

FIG. 2D is an exemplary schematic cross-sectional view of the substrate W during the process of step S104. Here, SiH₄ is selectively adsorbed onto the conductive layer 120 relative to the insulating layer 110. By selectively adsorbing SiH₄ onto the conductive layer 120, an oxidation suppression layer 130 that suppresses oxidation of Cu is formed on the surface of the conductive layer 120. The oxidation suppression layer 130 is formed by bonding Cu with an atom (e.g., Si and/or Al) that forms a stronger bond with O (oxygen) than a bond of Cu—O.

The process of selectively forming the oxidation suppression layer 130 on the surface of the conductive layer 120 can be performed in a single process.

The process of step S104 is performed in a low-temperature range such as 100 degrees C. In addition, the process of step S104 may be performed in a temperature range of 0 degrees C. to 400 degrees C.

The processes illustrated in steps S103 and S104 are desirably performed in a vacuum atmosphere or may be performed in an atmosphere-controlled manner. In the case of the atmosphere-controlled manner, a gas that does not react with the active surface or has a difficulty in reacting with the active surface can be used as an atmosphere gas. The process illustrated in step S103 and the process illustrated in step S104 may be performed in the same plasma processing apparatus. The plasma processing apparatus that performs the process illustrated in step S103 and the plasma processing apparatus that performs the process illustrated in step S104 may have configurations in which they are connected to a vacuum transfer chamber or an atmosphere-controlled transfer chamber. This prevents a natural oxide film from being formed on the surface of the conductive layer 120 after the process illustrated in step S103 and before the process illustrated in step S104.

In step S105, the substrate W is spin-cleaned using a water scrubber processing module. In step S106, the substrate W is dried using the water scrubber processing module.

FIG. 3A is an exemplary schematic cross-sectional view of the substrate W during the process of step S105. FIG. 3B is an exemplary schematic cross-sectional view of the substrate W after step S106. The water scrubber processing module spin-cleans the surface of the substrate W by supplying water from a liquid supply portion (not illustrated) to the surface of the substrate W placed on a rotating stage (not illustrated) in an air atmosphere and rotating the rotating stage to rotate the substrate W. Here, as illustrated in FIG. 3A, a water molecule 400 is present on the surface of the substrate W. The water molecule 400 reacts with the active surface (not illustrated) formed on the surface of the insulating layer 110, and thus the hydroxyl group 410 is bonded to the surface of the insulating layer 110 as illustrated in FIG. 3B.

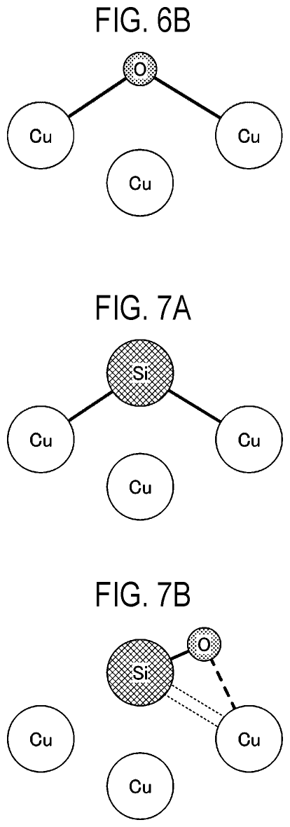

Here, the oxidation suppression layer 130 formed on the surface of the conductive layer 120 suppresses the bonding of O (oxygen) with Cu, as described later with reference to FIGS. 7A and 7B. In addition, the oxidation suppression layer 130 suppresses photocorrosion, as described later with reference to FIG. 5.

In step S107, substrate alignment is performed using a substrate bonding processing module as a preparation for bonding two substrates W.

FIG. 3C is an exemplary schematic cross-sectional view of the substrates W after step S107. Each of a lower substrate W1 and an upper substrate W2 has undergone the processes from steps S101 to S106. That is, the hydroxyl group 410 has been bonded to the surface of the insulating layer 110, and the oxidation suppression layer 130 has been formed on the surface of the conductive layer 120. Here, the substrates W1 and W2 are aligned.

In step S108, the two substrates W are bonded using the substrate bonding processing module.

FIG. 3D is an exemplary schematic cross-sectional view of the substrates W in step S108. The substrates W1 and W2 are bonded by combining the hydroxyl group 410 formed on the surface of the lower substrate W1 and the hydroxyl group 410 formed on the surface of the upper substrate W2 with each other and removing H2O.

In step S109, a bonded substrate W3 is annealed using a heat treatment module. An annealing temperature is, for example, within a range of 300 degrees C. to 400 degrees C. The annealing temperature is not limited thereto.

FIG. 4A is an exemplary schematic cross-sectional view of the substrate W3 before an annealing process. The substrates W1 and W2 (see FIG. 3D) are bonded to form the bonded substrate W3. Here, the oxidation suppression layer 130 is formed on a boundary surface between the upper and lower conductive layers 120. In addition, even in the oxidation suppression layer 130 (especially the oxidation suppression layer using Si), since the same bonding can be formed between the substrate W1 and the substrate W2, bonding strength is improved by forming a bond even between the oxidation suppression layers 130.

FIG. 4B is an exemplary schematic cross-sectional view of the substrate W3 after the annealing process. The upper and lower conductive layers 120 are bonded by diffusing Cu of the conductive layer 120 of the lower substrate W1 (see FIG. 3D) and Cu of the conductive layer 120 of the upper substrate W1 (see FIG. 3D) to each other.

As described above, the two substrates W (W1 and W2) each having the insulating layer 110 and the conductive layer 120 are bonded. That is, the bonding of the insulating layers 110 is achieved by bonding between the hydroxyl groups 410 of the insulating layers 110. Further, the bonding of the conductive layers 120 is achieved by mutual diffusion of Cu by heat treatment (annealing process).

A substrate processing system for performing the substrate bonding process illustrated in FIGS. 2A to 4B includes the CMP processing module, one or plural plasma processing apparatuses, the water scrubber processing module, the substrate bonding processing module, and the heat treatment module.

Here, photocorrosion that occurs when the conductive layer 120 is spin-cleaned (see step S105) will now be described with reference to FIG. 5. FIG. 5 is an exemplary schematic cross-sectional view of the substrate W for explaining photocorrosion. In FIG. 5, a part of the surface of the substrate W is illustrated, and the other parts thereof are not illustrated.

Here, an example is described in which a semiconductor device (not illustrated) having a PN junction is formed on the substrate W, and a conductive layer 120A is connected to a P-type semiconductor and a conductive layer 120B is connected to an N-type semiconductor.

When the substrate W is spin-cleaned and the hydroxyl group 410 is bonded to the active surface of the insulating layer 110 using the water scrubber processing module, the surface of the substrate W is supplied with water (the water molecule 400).

If the surface of the substrate W is spin-cleaned in a state in which it is still an active surface, corrosion occurs due to a reaction between the active surface of Cu (conductive layer 120) and water. This may reduce the flatness of a bonding surface of the substrate W. In addition, as the surface of the substrate W is irradiated with light for alignment (see step S106) in a state in which the surface of the substrate W is wetted with water by spin cleaning, electromotive force is generated in the semiconductor device having the PN junction due to a photoelectric effect. Thereby, Cu 126 is eluted from the conductive layer 120A, and the eluted Cu 126 is formed as a precipitate 127 on the side of the conductive layer 120B. Therefore, there is a concern that the flatness of the bonding surface of the substrate (W) may deteriorate.

In contrast, according to the bonding method of the substrate W illustrated in FIGS. 2A to 4B, the oxidation suppression layer 130 is formed on the surface of the conductive layer 120 by the selective surface process of step S104. This suppresses the reaction between the active surface of Cu (the conductive layer 120) and water. In addition, even if a potential difference occurs due to the photoelectric effect between the conductive layers 120A and 120B in steps S105 and S106, the elution of Cu from the conductive layer 120A can be suppressed. This also suppresses the precipitation of Cu in the conductive layer 120B. In addition, bonding defects can be prevented when bonding the substrates W1 and W2.

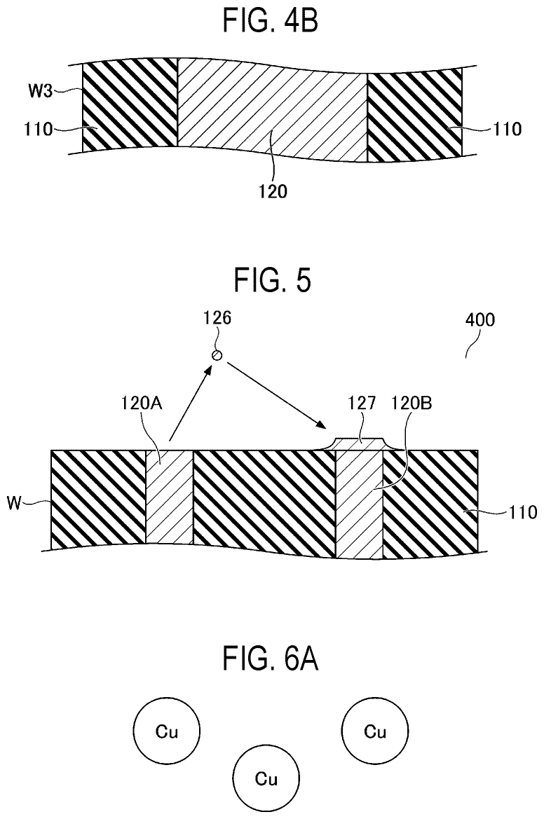

Next, the oxidation of the conductive layer 120 when the substrate W is spin-cleaned (see step S105) will be described with reference to FIGS. 6A, 6B, 7A, and 7B.

FIGS. 6A and 6B are exemplary model diagrams illustrating oxidation of the conductive layer 120 in a reference example. Here, in a bonding method of the reference example, after the plasma activation process (see step S103), the substrate W is spin-cleaned (see step S105). As illustrated in FIG. 2C, the outermost surface of the conductive layer 120 before the spin cleaning process is formed of Cu. FIG. 6A schematically illustrates the state of the outermost surface of the conductive layer 120 before the spin cleaning process. The outermost surface of the conductive layer 120 is formed of Cu.

Here, the spin cleaning process is performed in an air atmosphere. Therefore, as illustrated in FIG. 6B, Cu is bonded with O in the air or O in cleaning water, thereby forming copper oxide. In this case, fine defects (voids) are formed on the surface of the conductive layer 120. As a result, there is a concern that the reliability of the conductive layer 120 after bonding may deteriorate. In addition, the resistance of the conductive layer 120 after bonding may increase.

FIGS. 7A and 7B are exemplary model diagrams illustrating oxidation of the conductive layer 120 according to the present disclosure. In the bonding method according to the present disclosure, the oxidation suppression layer 130 is formed on the surface of the conductive layer 120 (see step S104) after the plasma activation process (see step S103), and after that the substrate W is spin-cleaned (see step S105). As illustrated in FIG. 2D, the oxidation suppression layer 130 is formed on the outermost surface of the conductive layer 120 before spin cleaning. FIG. 7A schematically illustrates the state of the outermost surface of the conductive layer 120 before spin cleaning. In the oxidation suppression layer 130, Cu and Si are bonded.

Here, since a bond of Si—O is stronger than a bond of Cu—O, O is bonded with Si as illustrated in FIG. 7B. This makes it possible to suppress the bond of Cu—O. Thereby, an increase in the electrical resistance of the conductive layer 120 after the annealing process can be suppressed.

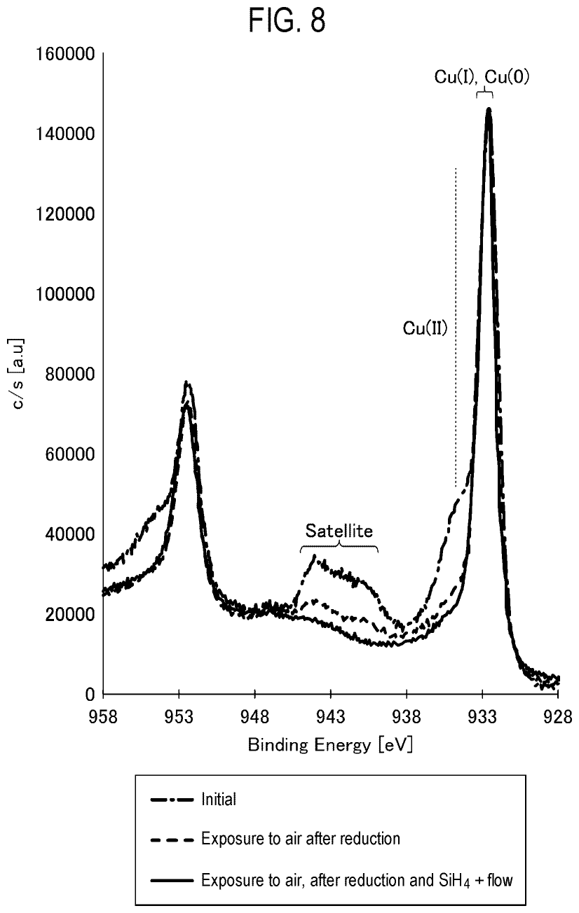

The effect of the substrate bonding method according to the present disclosure will now be described with reference to FIGS. 8 to 10. Here, the conductive layer 120 was simulated by forming a Cu film on the substrate and X-ray photoelectron spectroscopy (XPS) analysis of the Cu film was performed.

FIGS. 8 to 11 are graphs illustrating exemplary XPS analysis results of the Cu film formed on the substrate. Here, the conductive layer 120 was simulated by forming a Cu film in a physical vapor deposition (PVD) method in an experiment and the XPS analysis was performed on the substrate. “Initial” represented by a dashed-dotted line indicates the XPS analysis result of the substrate on which the Cu film is formed by the PVD method. “Exposure to air after reduction” represented by a broken line indicates the XPS analysis result of the substrate on which the Cu film is formed by the PVD method, in which the substrate is exposed to the air after reducing the Cu film using H₂ plasma. “Exposure to air, after reduction and SiH₄+flow” represented by a solid line indicates the XPS analysis result of the substrate on which the Cu film is formed by the PVD, in which the substrate is exposed to the air after reducing the Cu film using H₂ plasma and then exposing the substrate to SH₄ gas. The horizontal axis represents binding energy, and the vertical axis represents the number of detections per unit time.

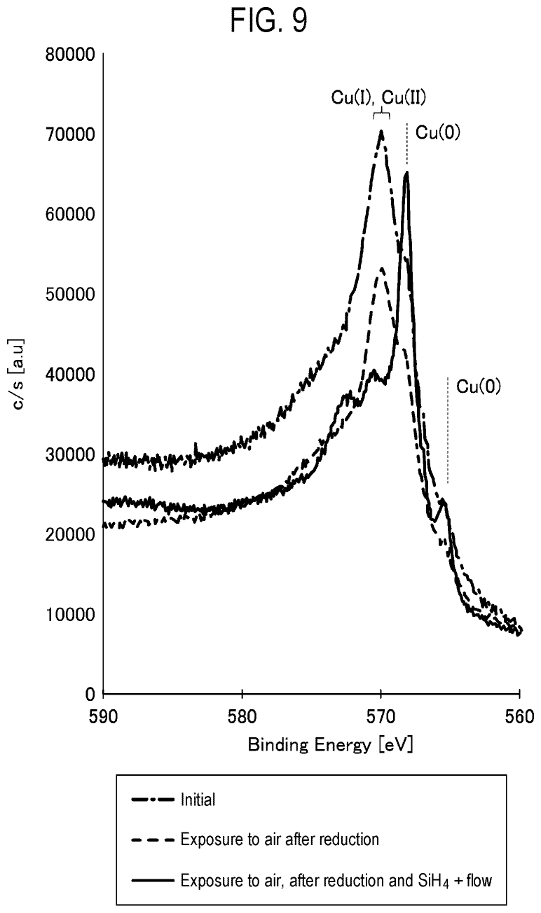

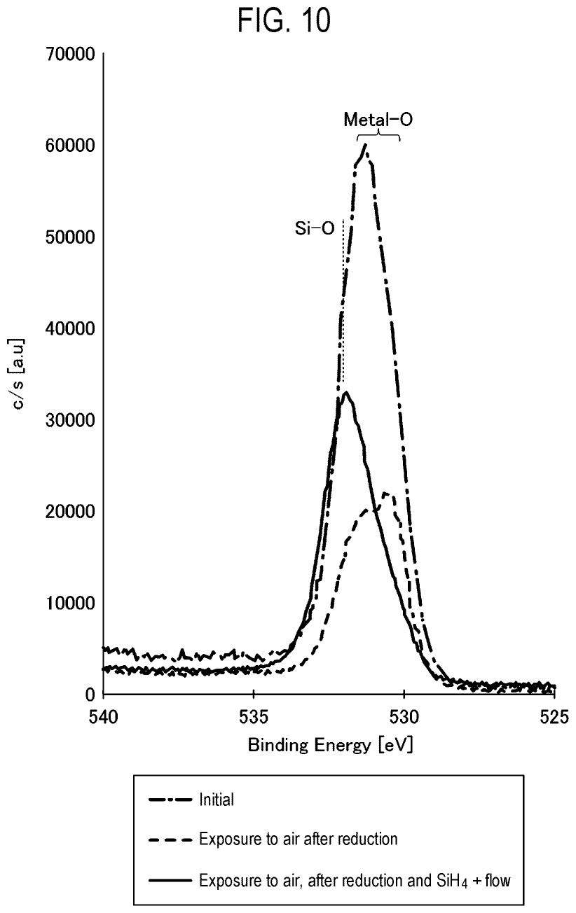

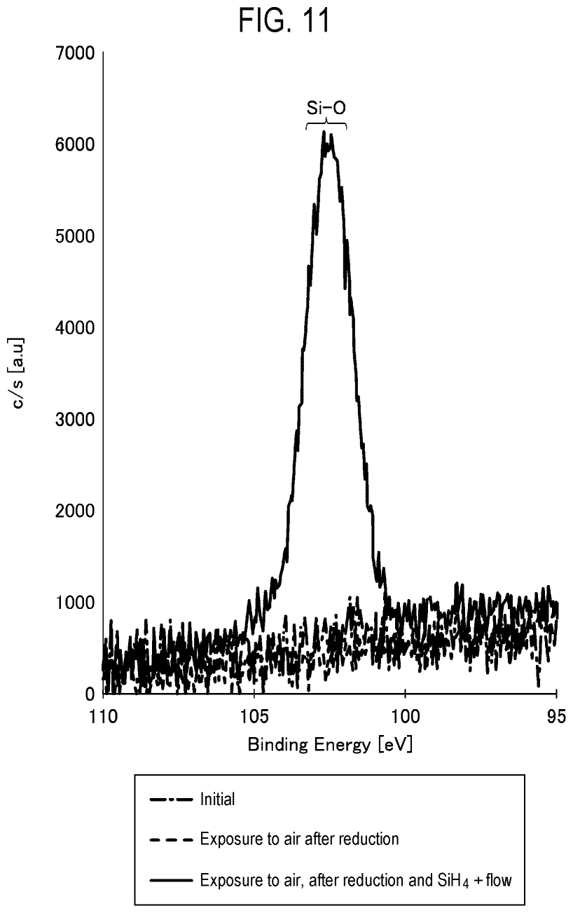

FIG. 8 illustrates an XPS analysis result of Cu2/3 p. FIG. 9 illustrates an XPS analysis result of Cu LMM. FIG. 10 illustrates an XPS analysis result of O1s. FIG. 11 illustrates an XPS analysis result of Si2 p.

The XPS results of Cu2/3 p illustrated in FIG. 8 and Cu LMM illustrated in FIG. 9 show that “Exposure to air after reduction” represented by the broken line tends to return to the “Initial” state represented by the dashed-dotted line as Cu is oxidized by exposure to the air. In contrast, in “Exposure to air, after reduction and SiH4+flow” represented by the solid line, it shows that returning to the “Initial” state represented by the dashed-dotted line after exposure to the air was not shown and oxidation of Cu is suppressed.

In addition, peaks of the XPS result of O1s illustrated in FIG. 10 show that “Initial” represented by the dashed-dotted line and “Exposure to air after reduction” represented by the broken line are shifted to a low energy side, and thus a bonding state of O is biased toward bonding with Cu. In contrast, “Exposure to air, after reduction and SiH4+flow” represented by the solid line is shifted to a high energy side, and thus the bonding state of O is mainly made by the bonding with Si.

Further, the XPS result of Si2 p illustrated in FIG. 11 shows that a signal of Si2 p appears only in “Exposure to air, after reduction and SiH4+flow” represented by the solid line. This bonding state also indicates that oxygen exists in the form of SiOx.

As described above, in the case of “Exposure to air, after reduction and SiH4+flow” represented by the solid line, oxygen (O) is bonded with Si, thereby suppressing oxidation of Cu due to exposure to the air.

According to one aspect of the present disclosure, it is possible to provide a substrate processing method, a plasma processing apparatus, and a substrate processing system that suppress defects when bonding substrates having a conductive layer containing Cu and an insulating layer.

While the substrate processing method has been described, the present disclosure is not limited to the above embodiments. Various modifications and improvements can be made within the scope of the present disclosure described in the claims.

The present application claims priority based on Japanese Patent Application No. 2022-184422 filed on Nov. 17, 2022, the disclosure of which is incorporated herein in its entirety by reference.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing method comprising:
activating a surface of a substrate having a conductive layer containing Cu and an insulating layer by exposing the substrate to plasma of a first process gas;
forming an oxidation suppression layer that suppresses oxidation of Cu on a surface of the conductive layer by exposing the substrate, after activating the surface of the substrate, to plasma of a second process gas;
forming a hydroxyl group on the surface of the substrate by supplying water to the surface of the substrate after forming the oxidation suppression layer;
bonding the substrate after forming the hydroxyl group to another substrate after forming the hydroxyl group; and
heat-treating the bonded substrates.

2. The substrate processing method of claim 1, wherein the first process gas is a gas containing H and/or N.

3. The substrate processing method of claim 2, wherein the first process gas is any one of H₂ gas, N₂ gas, NH₃ gas, a mixed gas of H₂ and N₂, and a mixed gas of H₂ and NH₃.

4. The substrate processing method of claim 1, wherein the forming the oxidation suppression layer includes selectively forming the oxidation suppression layer on the conductive layer relative to the insulating layer.

5. The substrate processing method of claim 4, wherein the second process gas is a gas containing Si and/or Al.

6. The substrate processing method of claim 5, wherein the second process gas is any one of SiH₄, Si₂H₆, SiCl₄, Si₂Cl₂H₂, Si₂Cl₆, AlCl₃, Al(CH₃)₃, and AlH(CH₃)₂.

7. The substrate processing method of claim 1, further comprising polishing the surface of the substrate before activating the surface of the substrate.

8. The substrate processing method of claim 7, further comprising forming the surface of the conductive layer to be lower than a surface of the insulating layer after polishing the surface of the substrate and before activating the surface of the substrate.

9. A plasma processing apparatus configured to perform in a vacuum atmosphere:
activating a surface of a substrate having a conductive layer containing Cu and an insulating layer by exposing the substrate to plasma of a first process gas; and
forming an oxidation suppression layer that suppresses oxidation of the Cu on a surface of the conductive layer by exposing the substrate after activating the surface of the substrate to plasma of a second process gas.

10. A substrate processing system, comprising:
the plasma processing apparatus of claim 9;
a module configured to polish the substrate in an air atmosphere;
a module configured to supply water to the surface of the substrate in an air atmosphere;
a module configured to bond the substrate in an air atmosphere; and
a module configured to heat-treat the substrate.

11. The substrate processing method of claim 2, wherein the forming the oxidation suppression layer includes selectively forming the oxidation suppression layer on the conductive layer relative to the insulating layer.

12. The substrate processing method of claim 3, wherein the forming the oxidation suppression layer includes selectively forming the oxidation suppression layer on the conductive layer relative to the insulating layer.
